(19) United States
(12) Patent Application Publication
(10) Pub. No.: US 2025/0210435 A1
(43) Pub. Date: Jun. 26, 2025

(54) SEMICONDUCTOR MODULE AND METHOD OF PRODUCING SEMICONDUCTOR MODULE

(71) Applicant: Murata Manufacturing Co., Ltd., Kyoto-fu (JP)

(72) Inventor: Akira FUJIHARA, Nagaokakyo-shi (JP)

(73) Assignee: Murata Manufacturing Co., Ltd., Kyoto-fu (JP)

(21) Appl. No.: 19/075,893

(22) Filed: Mar. 11, 2025

Related U.S. Application Data
(63) Continuation of application No. PCT/JP2023/035139, filed on Sep. 27, 2023.

(30) Foreign Application Priority Data
Oct. 3, 2022 (JP) 2022-159677

(51) Int. Cl. H01L 23/31; H01L 21/56; H01L 23/00

(52) U.S. Cl. CPC H01L 23/315; H01L 21/56; H01L 23/3135; H01L 24/16; H01L 24/81; H01L 2224/16227; H01L 2224/81191

(57) ABSTRACT

A semiconductor device includes a device layer including an electronic circuit including a semiconductor element, an insulating layer on one of surfaces of the device layer, and bumps that are on another of the surfaces of the device layer. The semiconductor device is mounted on a mounting substrate of a mounting substrate, with the another of the surfaces, where the bumps are disposed, of the device layer facing the mounting surface. A resin layer is on a surface of the insulating layer on a side opposite to the device layer. A mold material is on a region of the mounting surface on an outer side portion of the semiconductor device in plan view, a side surface of the semiconductor device, and at least a side surface of the resin layer. A dielectric dissipation factor of the resin layer is smaller than a dielectric dissipation factor of the mold material.

### CROSS-REFERENCE TO RELATED APPLICATIONS

This application claims benefit of priority to International Patent Application No. PCT/JP2023/035139, filed Sep. 27, 2023, and to Japanese Patent Application No. 2022-159677, filed Oct. 3, 2022, the entire contents of each are incorporated herein by reference.

### BACKGROUND

### Technical Field

The present disclosure relates to a semiconductor module and a method of producing the semiconductor module.

### Background Art

In a high-frequency integrated circuit using a silicon (Si) substrate, electrical loss caused by electrical resistance of the Si substrate that is conductive or parasitic capacitance between a wire on the Si substrate and the Si substrate occurs. When the high-frequency integrated circuit is a switch integrated circuit or a low-noise-amplifier integrated circuit, the electrical resistance of the Si substrate and the parasitic capacitance between the wire and the Si substrate adversely affect loss characteristics and noise characteristics.

By using an SOI substrate in which an embedded oxide layer is inserted between an Si substrate and an element formation layer where a semiconductor element is formed, it is possible to reduce the effects of electrical resistance of the Si substrate and parasitic capacitance between the Si substrate and the wire. Further, by removing the Si substrate and leaving the element formation layer and the embedded oxide layer, it is possible to remove the effects of electrical resistance of the Si substrate and parasitic capacitance between the Si substrate and the wire as described, for example, in International Publication No. 2018/031995.

### SUMMARY

When producing a high-frequency module by mounting onto a mounting substrate a die having a structure in which an Si substrate of an SOI substrate is removed and an element formation layer and an embedded oxide layer are left, in general, the die mounted on the mounting substrate is sealed with a mold resin. In general, the dielectric dissipation factor of the mold material is larger than the dielectric dissipation factor of, for example, an insulating layer. Therefore, electrical loss occurs due to high-frequency electric power that has leaked to the mold material from a high-frequency circuit of the element formation layer. It is an object of the present disclosure to provide a semiconductor module that is capable of reducing electrical loss caused by the mold material, and a method of producing the semiconductor module.

According to an aspect of the present disclosure, there is provided a semiconductor module comprising a mounting substrate that has a mounting surface; and a semiconductor device that includes a device layer where an electronic circuit including a semiconductor element is formed, an insulating layer that is disposed on one of surfaces of the device layer, and a plurality of bumps that are disposed on another of the surfaces of the device layer, the semiconductor device being mounted on the mounting substrate with the another of the surfaces, where the plurality of bumps are disposed, of the device layer facing the mounting surface. The semiconductor module also comprises a resin layer that is disposed on a surface of the insulating layer on a side opposite to the device layer; and a mold material that is disposed on a region of the mounting surface on an outer side portion of the semiconductor device in plan view, a side surface of the semiconductor device, and at least a side surface of the resin layer. A dielectric dissipation factor of the resin layer is smaller than a dielectric dissipation factor of the mold material.

According to another aspect of the present disclosure, there is provided a method of producing a semiconductor module, comprising preparing an SOI wafer in which an insulating layer and a device layer that is made of a semiconductor are placed on a base substrate that is made of a semiconductor, and in which a plurality of chip regions are defined; forming a plurality of semiconductor elements on each of the plurality of chip regions of the device layer; forming a multilayer wire layer on the device layer where the plurality of semiconductor elements are formed; and forming a plurality of bumps on the multilayer wire layer. Also, after forming the plurality of bumps, removing the base substrate and forming the SOI wafer into a thin layer; disposing a resin layer on an exposed surface of the insulating layer of the SOI wafer that has been formed into the thin layer; after disposing the resin layer, cutting the SOI wafer and the resin layer into individual parts to form a plurality of semiconductor devices; mounting one of the plurality of semiconductor devices on a mounting surface of a mounting substrate by flip-chip mounting; and covering with a mold material a region of the mounting surface on an outer side portion of the semiconductor device in plan view and at least a side surface of the semiconductor device. A dielectric dissipation factor of the resin layer is smaller than a dielectric dissipation factor of the mold material.

Since the dielectric dissipation factor of the resin layer is smaller than the dielectric dissipation factor of the mold material, compared to a structure in which a semiconductor device is covered with a mold material without disposing a resin layer, it is possible to reduce electrical loss caused by the dielectric dissipation factor.

### BRIEF DESCRIPTION OF THE DRAWINGS

FIG. 1 is a sectional view of a semiconductor module according to a first embodiment;

FIG. 2 is a sectional view showing in an enlarged form a portion of the semiconductor module according to the first embodiment;

FIGS. 3A to 3D are each a schematic sectional view of a stage in the middle of producing the semiconductor module according to the first embodiment;

FIG. 4 is a sectional view of a semiconductor module according to a second embodiment;

FIG. 5 is a sectional view showing in an enlarged form a portion of the semiconductor module according to the second embodiment;

FIG. 6 illustrates positional relationships of a plurality of bumps in plan view;

FIG. 7 is a sectional view of a semiconductor module according to a third embodiment;

FIGS. 8A to 8G are each a sectional view of a stage in the middle of producing the semiconductor module according to the third embodiment;

FIGS. 9A and 9B are each a sectional view of a stage in the middle of producing the semiconductor module according to the third embodiment; and

FIG. 10 is a semiconductor module according to a fourth embodiment.

### DETAILED DESCRIPTION

### First Embodiment

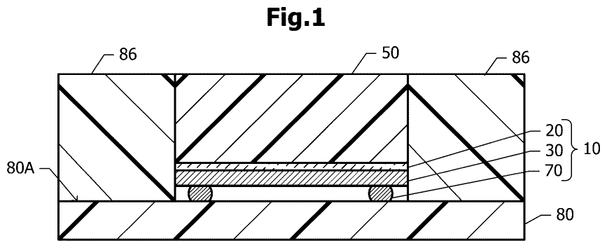

With reference to FIGS. 1 to 3D, a semiconductor module according to a first embodiment is described.

FIG. 1 is a sectional view of the semiconductor module according to the first embodiment. The semiconductor module according to the first embodiment includes a semiconductor device 10, a mounting substrate 80, a resin layer 50, and a mold material 86. The semiconductor device 10 includes a device layer 30, an insulating layer 20, and a plurality of bumps 70. An electronic circuit including a plurality of semiconductor elements, such as transistors, is formed on the device layer 30. The insulating layer 20 is disposed on one of the surfaces of the device layer 30. The plurality of bumps 70 are disposed on the other surface of the device layer 30.

The semiconductor device 10 is mounted on a mounting surface 80A, which is one of the surfaces of the mounting substrate 80, by flip-chip mounting. That is, the plurality of bumps 70 are fixed to a plurality of lands (not shown) that are disposed on the mounting surface 80A of the mounting substrate 80, and are electrically connected. There is a cavity between the device layer 30 and the mounting substrate 80.

The resin layer 50 is disposed on a surface of the insulating layer 20 on a side opposite to the device layer 30. When the mounting surface 80A is seen in plan view (hereunder referred to as “in the plan view”), the positions of edges of the device layer 30, the insulating layer 20, and the resin layer 50 substantially correspond with each other.

The mold material 86 closely contacts a region of the mounting surface 80A on an outer side portion of the semiconductor device 10 in the plan view, side surfaces of the semiconductor device 10, and side surfaces of the resin layer 50. A top surface of the resin layer 50 and a top surface of the mold material 86 are positioned on substantially the same imaginary plane. Here, the “top surface” means a surface facing a side opposite to the mounting substrate 80. By the mold material 86, the cavity between the device layer 30 and the mounting substrate 80 is separated from the outside.

For example, a printed wiring board is used for the mounting substrate 80. For example, a filler-containing epoxy resin is used for the resin layer 50. For example, an epoxy resin or a filter-containing epoxy resin is used for the mold material 86. The dielectric dissipation factor of the resin layer 50 is smaller than the dielectric dissipation factor of the mold material 86. As an example, by using a filter-containing epoxy resin for the resin layer 50 and adjusting the filling factor of the filler, the dielectric dissipation factor of the resin layer 50 can be easily made smaller than the dielectric dissipation factor of the mold material 86.

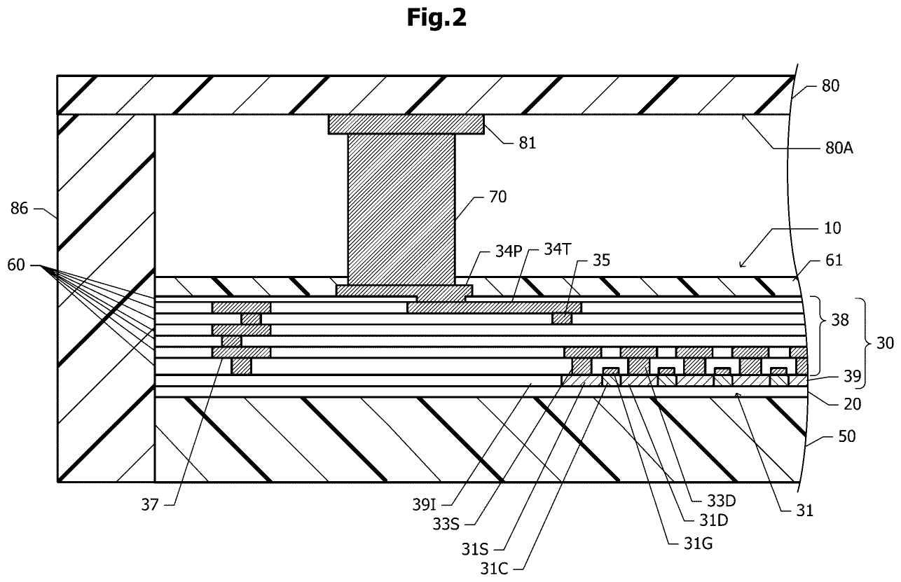

FIG. 2 is a sectional view showing in an enlarged form a portion of the semiconductor module according to the first embodiment. Note that, in FIG. 2, dimensional ratios between the structural elements and dimensional ratios of the structural elements in a thickness direction and an in-plane direction are not actual ratios. In addition, FIG. 2 illustrates the semiconductor module with the upper and lower sides in FIG. 1 being reversed.

The semiconductor device 10 includes the device layer 30, the insulating layer 20, a protective film 61, and the bumps 70. Note that FIG. 1 does not illustrate the protective film 61. FIG. 2 illustrates only one of the plurality of bumps 70. The insulating layer 20 is made of, for example, silicon oxide. As the bumps 70, for example, solder bumps, Cu pillar bumps, or Au bumps are used.

The semiconductor device 10 is mounted on the mounting substrate 80. In the description with reference to FIG. 2, a direction from the semiconductor device 10 toward the mounting substrate 80 is defined as an upward direction. The device layer 30 is disposed on a surface of the insulating layer 20 facing upward, and the resin layer 50 is disposed on a surface of the insulating layer 20 facing downward.

The device layer 30 includes an element formation layer 39 that contacts the insulating layer 20 and that is made of a semiconductor, and a multilayer wire layer 38 that is disposed on the element formation layer 39. The element formation layer 39 includes an active region that is made of silicon, and an insulating element isolation region 391 that surrounds the active region. A plurality of source regions 31S, a plurality of drain regions 31D, and a plurality of channel regions 31C of the semiconductor elements 31 that are MOSFETs are disposed in the active region of the element formation layer 39.

The plurality of source regions 31S and the plurality of drain regions 31D are disposed apart from each other and side by side in one direction (left-right direction in FIG. 2). The drain regions 31D and the source regions 31S extend in a thickness direction of the element formation layer 39 from one of the surfaces of the element formation layer 39 and reach the other surface of the element formation layer 39. The channel regions 31C are each defined between the source region 31S and the drain region 31D that are adjacent to each other. Each gate electrode 31G is disposed on the channel region 31C with a gate insulating film (not shown) interposed therebetween.

The multilayer wire layer 38 on the element formation layer 39 includes a plurality of interlayer insulating films 60. For example, a material having a low dielectric constant (Low-k material) is used for the plurality of interlayer insulating films 60. Via holes provided in the lowest interlayer insulating film 60 of the multilayer wire layer 38 are filled with source contact electrodes 33S and drain contact electrodes 33D. The source contact electrodes 33S contact the source regions 31S by ohmic-contact, and the drain contact electrodes 33D contact the drain regions 31D by ohmic-contact. The source contact electrodes 33S and the drain contact electrodes 33D are made of, for example, W. If necessary, for the purpose of increasing contactability, a close-contact layer made of, for example, TiN may be disposed. Note that a film made of metal silicide, such as CoSi or NiSi, may be formed on a surface of each source region 31S and a surface of each drain region 31D to form a structure that decreases the resistance of each contact portion.

A plurality of wires 34 and a plurality of vias 35 are disposed in the plurality of interlayer insulating films 60 of a second layer and subsequent layers. The wires 34 and the vias 35 are formed by using a damascene method, a dual damascene method, or a subtractive method. A plurality of wires 34T are disposed at an uppermost wire layer of the device layer 30, and a plurality of pads 34P are disposed on the uppermost interlayer insulating film 60. As an example, the wires 34 and 34T and the pads 34P are made of Cu or Al, and the vias are made of Cu or W. Note that, if necessary, for the purpose of preventing diffusion or increasing contactability, a close-contact layer made of, for example, TiN may be disposed. A metal layer 37 called a guard ring is disposed at a periphery of the multilayer wire layer.

The protective film 61 made of an organic insulating material is disposed on the device layer 30 so as to cover the pads 34P. Examples of the organic insulating material used for the protective film 61 include polyimide and benzocyclobutene (BCB). A plurality of openings where upper surfaces of the plurality of pads 34P are exposed are provided in the protective film 61, and the bumps 70 are disposed on the pads 34P in the openings. When Cu pillar bumps are used as the bumps 70, the bumps 70 each include an under bump metal layer, a Cu pillar, and a solder layer thereon. By connecting the bumps 70 to the lands 81 of the mounting substrate 80, the semiconductor device 10 is mounted on the mounting substrate 80 by flip-chip mounting.

The side surfaces of the semiconductor device 10 and the side surfaces of the resin layer 50 closely contact the mold material 86. The mold material 86 closely contacts, of the mounting surface 80A of the mounting substrate 80, a region on an outer side portion of the semiconductor device 10 in the plan view.

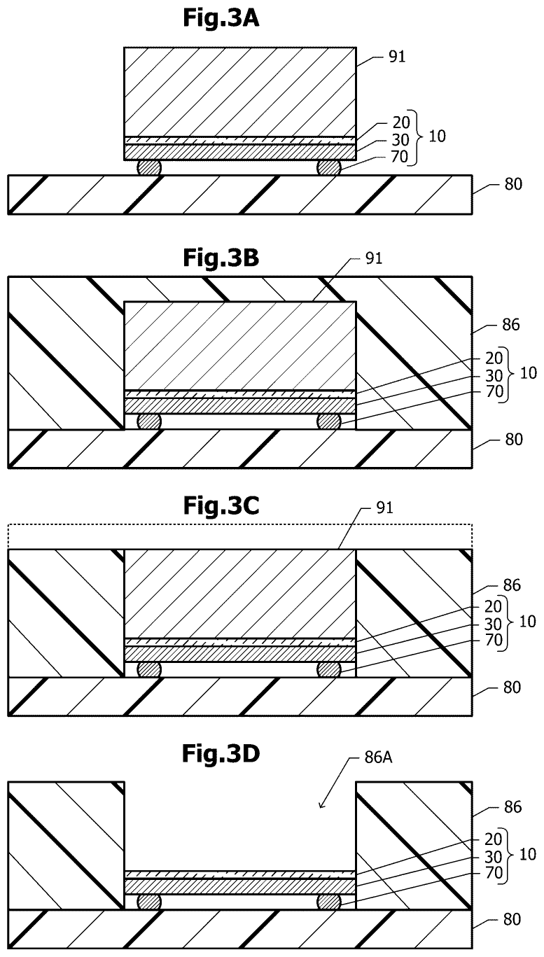

Next, a method of producing the semiconductor module according to the first embodiment is described with reference to FIGS. 3A to 3D. FIGS. 3A to 3D are each a schematic sectional view of a stage in the middle of producing the semiconductor module according to the first embodiment.

As shown in FIG. 3A, an intermediate product including a base substrate 91 that is made of silicon, the insulating layer 20 that is made of silicon oxide, the device layer 30, and the plurality of bumps 70 is formed. The intermediate product can be formed by using an SOI substrate and applying a general semiconductor wafer process and a dicing process. The base substrate 91, the insulating layer 20, and the element formation layer 39 (FIG. 2) correspond to a silicon substrate of the SOI substrate, an embedded oxide layer of the SOI substrate, and an SOI layer of the SOI substrate, the SOI layer being made of monocrystalline silicon. The intermediate product is mounted on the mounting substrate 80 by flip-chip mounting.

As shown in FIG. 3B, the intermediate product is sealed by the mold material 86. At this stage, the mold material 86 covers side surfaces and a top surface of the base substrate 91. A cavity is formed between the device layer 30 and the mounting substrate 80.

As shown in FIG. 3C, the top surface of the base substrate 91 is exposed by polishing or grinding the mold material 86 from its upper surface. Further, as shown in FIG. 3D, the exposed base substrate 91 (FIG. 3C) is etched and removed. Therefore, a recessed portion 86A is formed and the insulating layer 20 is exposed at a bottom side of the recessed portion 86A. By filling the recessed portion 86A with the resin layer 50 (FIG. 1), the semiconductor module is completed.

Next, excellent effects of the first embodiment are described.

The base substrate 91 made of silicon and shown in FIG. 3C is conductive. In a structure in which the base substrate 91 is left, parasitic capacitance occurs between the base substrate 91 and the high-frequency circuit of the device layer 30. The parasitic capacitance adversely affects loss characteristics and noise characteristics. In the first embodiment, since the base substrate 91 is removed and the insulating resin layer 50 (FIG. 1) is disposed in its place, it is possible to reduce the parasitic capacitance.

Since the insulating layer 20 corresponding to the embedded oxide layer of the SOI substrate is generally thin, that is, on the order of a few μm, electric power of a high-frequency signal that is transmitted through the circuit in the device layer 30 (FIG. 1) leaks to the resin layer 50 (FIG. 1), and electrical loss caused by the dielectric dissipation factor of the resin layer 50 occurs. In the first embodiment, since the dielectric dissipation factor of the resin layer 50 is smaller than the dielectric dissipation factor of the mold material 86, compared to a structure in which the insulating layer 20 is covered with the mold material 86, it is possible to reduce electrical loss caused by the dielectric dissipation factor.

Since, as the mold material 86, it is not particularly necessary to use a material having a small dielectric dissipation factor, the degree of freedom in selecting the mold material is increased. Therefore, a material that excels in various characteristics (mold characteristics) required of the mold material, such as high contactability, low stress, moisture resistance, and easy moldability, can be selected.

Since the mold material 86 having excellent mold characteristics closely contacts the side surfaces of the semiconductor device 10, it is possible to provide an excellent effect of increasing reliability.

Next, modifications of the first embodiment are described.

Although, in the first embodiment, a filler-containing epoxy resin is used for the resin layer 50 (FIG. 1), a dielectric material whose dielectric dissipation factor is smaller than the dielectric dissipation factor of the mold material 86, such an epoxy-resin-based dielectric, polytetrafluoroethylene (PTFE), a liquid crystal polymer (LCP) resin, polyphenylene ether (PPE), or fluorine-based elastomer, may be used. For the resin layer 50, it is preferable to use a dielectric material whose dielectric dissipation factor is less than 0.003.

Next, another modification of the first embodiment is described.

Although, in the first embodiment, the mold material 86 closely contacts, of the mounting surface of the mounting substrate 80, the region on the outer side portion of the semiconductor device 10 in the plan view, the side surfaces of the semiconductor device 10, and the side surfaces of the resin layer 50, the mold material 86 does not necessarily need to closely contact the entire regions of these surfaces. For example, an air gap may be provided between the mold material 86 and a region of at least a portion of the mounting surface 80A of the mounting substrate 80, a region of at least a portion of the side surfaces of the semiconductor device 10, and a region of at least a portion of the side surfaces of the resin layer 50. When a structure in which an air gap is provided between the mold material 86 and a region of at least a portion of the side surfaces of the semiconductor device 10 and the side surfaces of the resin layer 50 is used, and the semiconductor device 10 includes a high-frequency amplifier circuit, distortion characteristics and loss deterioration of the semiconductor module are suppressed.

### Second Embodiment

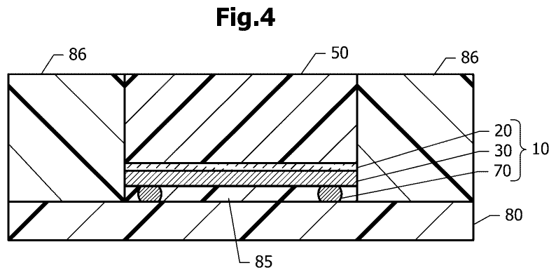

Next, with reference to FIGS. 4, 5, and 6, a semiconductor module according to a second embodiment is described. Structures that are common to those of the semiconductor module according to the first embodiment that have been described with reference to FIGS. 1 to 3D are not described below.

FIG. 4 is a sectional view of the semiconductor module according to the second embodiment. In the first embodiment (FIG. 1), a cavity is formed between the device layer 30 and the mounting substrate 80. In contrast, in the second embodiment, a first member 85 is disposed between a device layer 30 and a mounting substrate 80. As the first member 85, for example, a filler-containing epoxy resin is used. The dielectric dissipation factor of the first member 85 is smaller than the dielectric dissipation factor of a mold material 86. For example, at the stage in the middle of the production process shown in FIG. 3A, a space between the device layer 30 and the mounting substrate 80 may be filled with the first member 85 by using a capillary flow method. The entire space between the device layer 30 and the mounting substrate 80 need not be filled with the first member 85, and the first member 85 may be disposed in only a portion of the space.

Next, excellent effects of the second embodiment are described.

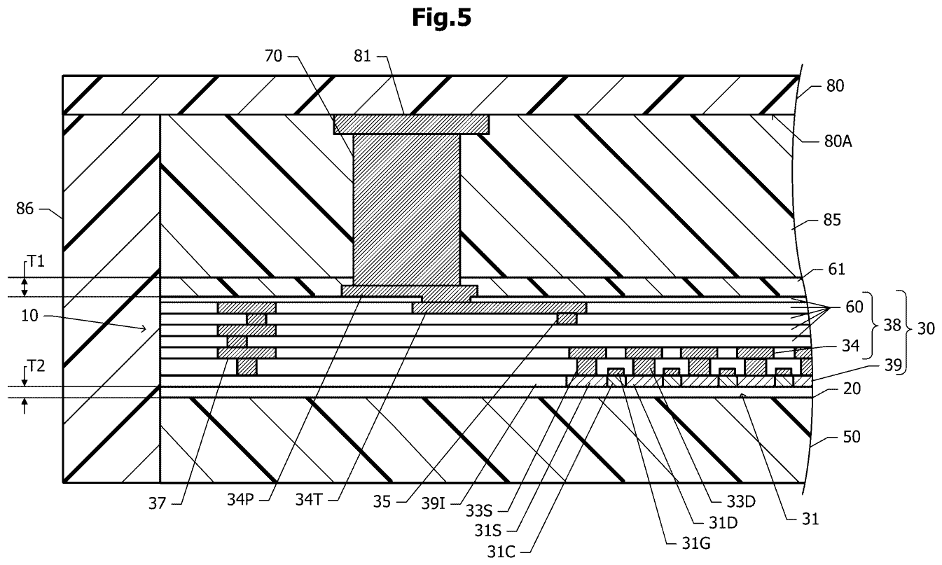

In the second embodiment, it is possible to increase resistance against external force and stress by filling the space between the device layer 30 and the mounting substrate 80 with the first member 85. Since the dielectric dissipation factor of the first member 85 is smaller than the dielectric dissipation factor of the mold material 86, it is possible to suppress an increase in electrical loss occurring due to leakage into the first member 85 of electric power of a high-frequency signal that is transmitted through a circuit of the device layer 30. In particular, electric power of a high-frequency signal that is transmitted through wires 34T (see FIG. 5) of an uppermost layer of a multilayer wire layer 38 tends to leak into the first member 85. When, of the wires 34T of the uppermost layer, a wire through which the high-frequency signal is transmitted is long, an excellent effect that the dielectric dissipation factor of the first member 85 is decreased becomes noticeable.

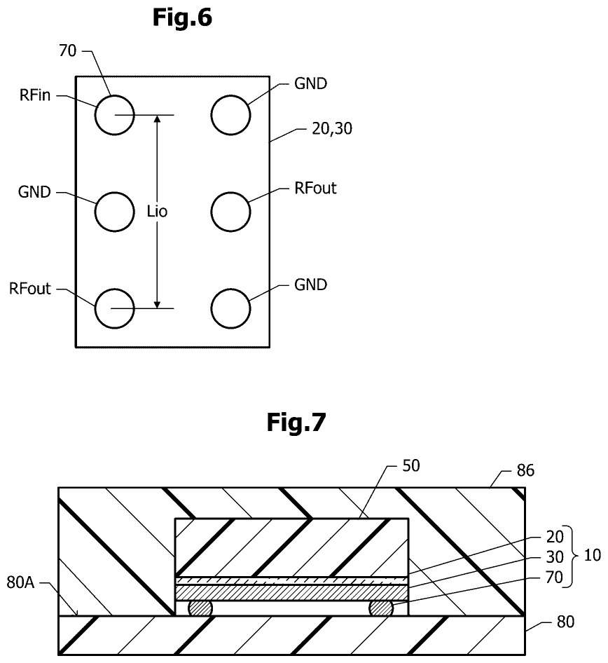

Next, with reference to FIGS. 5 and 6, preferable magnitude relationships between the dielectric dissipation factor of the resin layer 50 and the dielectric dissipation factor of the first member 85 are described.

FIG. 5 is a sectional view of a portion of the semiconductor module according to the second embodiment. A protective film 61 is disposed on a surface of the device layer 30 facing the mounting substrate 80. A space between the protective film 61 and the mounting substrate 80 is filled with the first member 85. The thickness of the protective film 61 is denoted by T1, and the thickness of an insulating layer 20 is denoted by T2.

FIG. 6 illustrates positional relationships of a plurality of bumps 70 in plan view. As an example, one of the plurality of bumps 70 is used as a terminal RFin for inputting a high-frequency signal, another two of the plurality of bumps 70 are used as terminals RFout for outputting a high-frequency signal, and the other plurality of bumps 70 are used as terminals GND for ground. The length of a longest line segment of line segments each connecting a geometric center of the terminal RFin for inputting a high-frequency signal and a geometric center of a corresponding one of the terminals RFout for outputting a high-frequency signal is denoted by Lio. Although, in FIG. 6, the shapes in plan view of the terminal RFin for inputting a high-frequency signal and the terminals RFout for outputting a high-frequency signal are circular, the shapes need not be circular. The shapes may be, for example, rounded square shapes or vertically elongated shapes that are long in one direction.

A plurality of terminals RFin for inputting a high-frequency signal may be disposed. In this case, the length of a longest line segment of line segments connecting geometric centers of the plurality of terminals RFin and respective geometric centers of the plurality of terminals RFout is to be denoted by Lio.

When the circuit formed on the device layer 30 (FIG. 5) is a high-frequency-signal power amplifier circuit, a high-frequency signal that has been input from the terminal RFin for inputting a high-frequency signal is transmitted through a wire 34 in the multilayer wire layer 38, is amplified by a semiconductor element 31, and is output from the terminals RFout for outputting a high-frequency signal. The terminal RFin for inputting a high-frequency signal and the terminals RFout for outputting a high-frequency signal are connected to the wires 34T in the uppermost layer, and the wires 34T in the uppermost layer are extended in an in-plane direction. Therefore, in general, when the length Lio is long, the wires 34T in the uppermost layer through which a high-frequency signal is transmitted become long.

With increasing lengths of the wires 34T in the uppermost layer or decreasing thickness T1 of the protective film 61, the electric power of the high-frequency signal that is transmitted in the device layer 30 tends to leak more to the first member 85 than to a resin layer 50. When the electric power of the high-frequency signal tends to leak more to the first member 85 than to the resin layer 50, the dielectric dissipation factor of the first member 85 is to be smaller than the dielectric dissipation factor of the resin layer 50. For example, when the length Lio is greater than or equal to 100 μm, or when the thickness T1 of the protective film 61 is less than the thickness T2 of the insulating layer 20, the dielectric dissipation factor of the first member 85 is to be smaller than the dielectric dissipation factor of the resin layer 50. In particular, when the length Lio is greater than or equal to 100 μm, and the thickness T1 is less than the thickness T2, the dielectric dissipation factor of the first member 85 is to be smaller than the dielectric dissipation factor of the resin layer 50. The dielectric dissipation factor of the first member 85 and the dielectric dissipation factor of the resin layer 50 can be adjusted by changing the filling factor of a filler that is contained in a matrix resin.

When the length Lio is less than 100 μm, and the thickness T2 is less than or equal to the thickness T1, the dielectric dissipation factor of the resin layer 50 is to be smaller than the dielectric dissipation factor of the first member 85.

### Third Embodiment

Next, a semiconductor module and a method of producing the semiconductor module according to the third embodiment are described with reference to FIGS. 7 to 9B. Structures that are common to those of the semiconductor module and to the method of producing the semiconductor module according to the first embodiment that have been described with reference to FIGS. 1 to 3D are not described below.

FIG. 7 is a sectional view of the semiconductor module according to the third embodiment. In the semiconductor module (FIG. 1) according to the first embodiment, the top surface of the resin layer 50 is exposed. In contrast, in the semiconductor module according to the third embodiment, a top surface and side surfaces of a resin layer 50 are covered with a mold material 86.

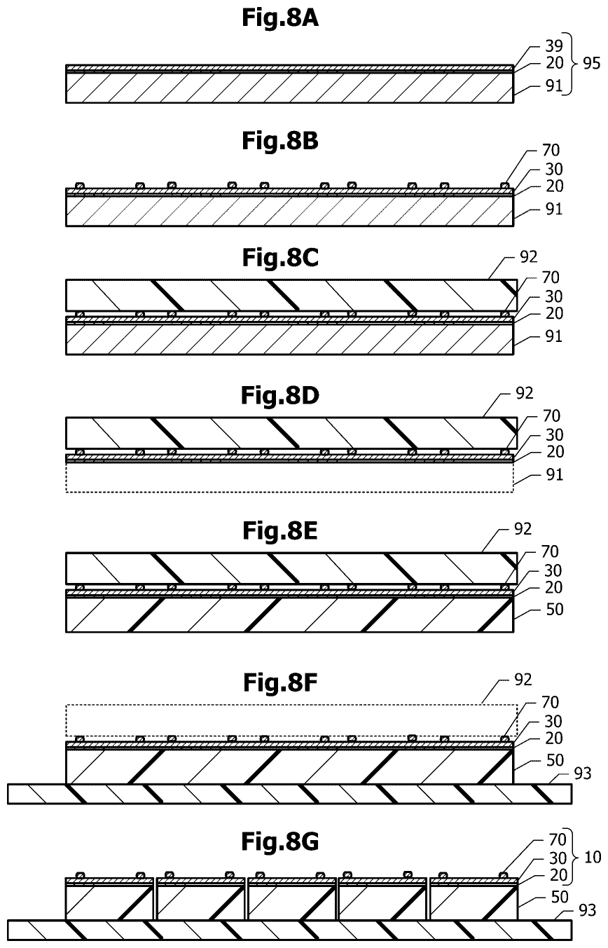

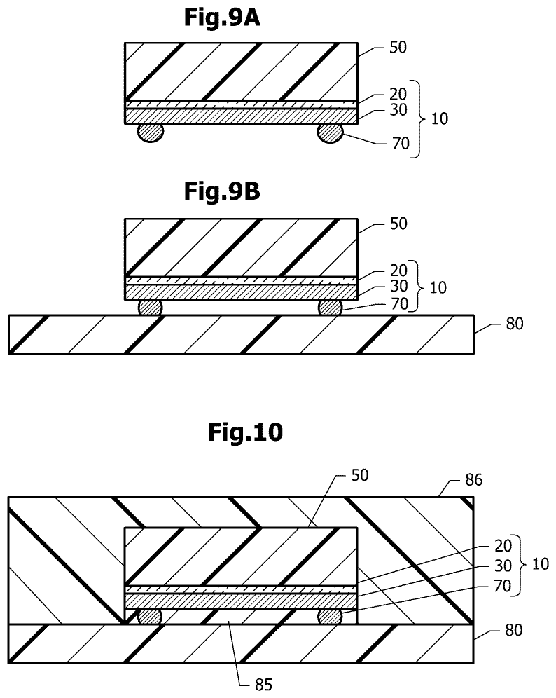

Next, the method of producing the semiconductor module according to the third embodiment is described with reference to FIGS. 8A to 9B. FIGS. 8A to 9B are each a sectional view of a stage in the middle of producing the semiconductor module according to the third embodiment.

First, as shown in FIG. 8A, an SOI wafer 95 including a base substrate 91 that is made of silicon, an insulating layer 20, and an element formation layer 39 that is made of monocrystalline silicon is prepared. In the SOI wafer 95, a plurality of chip regions are defined. Semiconductor elements 31 (FIG. 5) are formed on each of the plurality of chip regions of the element formation layer 39 (FIG. 8A), and a multilayer wire layer 38 (FIG. 5) is formed thereon. Therefore, as shown in FIG. 8B, the device layer 30 is formed. A plurality of bumps 70 are formed on the device layer 30. For these steps, a general semiconductor wafer process is used.

As shown in FIG. 8C, a temporary supporting substrate 92 is adhered to an end surface of each of the plurality of bumps 70. As shown in FIG. 8D, the base substrate 91 is etched and removed. This causes the insulating layer 20 to be exposed. With the base substrate 91 being removed, the temporary supporting substrate 92 mechanically supports the thin insulating layer 20 and the device layer 30.

As shown in FIG. 8E, a resin layer 50 is adhered to an exposed surface of the insulating layer 20. As the resin layer 50, for example, a resin substrate or an adhesive tape can be used. As shown in FIG. 8F, the resin layer 50 is attached to a dicing tape 93. Thereafter as shown in FIG. 8G, the resin layer 50, the insulating layer 20, and the device layer 30 are cut with a dicing machine into individual parts.

FIG. 9A is a sectional view of a semiconductor device 10 and the resin layer 50 formed by cutting into individual parts. As shown in FIG. 9B, the semiconductor device 10 is mounted on a mounting substrate 80. Thereafter, as shown in FIG. 7, a region of a mounting surface 80A on an outer side portion of the semiconductor device 10 in the plan view, side surfaces of the semiconductor device 10, and the side surfaces and the top surface of the resin layer 50 are covered with the mold material 86.

Next, excellent effects of the third embodiment are described.

Even in the third embodiment, the dielectric dissipation factor of the resin layer 50 disposed on the semiconductor device 10 is smaller than the dielectric dissipation factor of the mold material 86. Therefore, as in the first embodiment, it is possible to reduce electrical loss caused by the dielectric dissipation factor.

In the first embodiment, as shown in FIG. 3D, after the semiconductor device 10 formed by cutting into individual parts has been mounted on the mounting substrate 80 and has been sealed with the mold material 86, the resin layer 50 (FIG. 1) is formed. In contrast, in the third embodiment, as shown in FIG. 8E, before cutting into individual parts, the resin layer 50 is formed at a wafer level. Therefore, it is possible to reduce the number of steps after mounting the semiconductor device 10 on the mounting substrate 80.

### Fourth Embodiment

Next, with reference to FIG. 10, a semiconductor module according to a fourth embodiment is described. Structures that are common to those of the semiconductor module according to the third embodiment that has been described with reference to FIGS. 7 to 9B are not described below.

FIG. 10 is a sectional view of the semiconductor module according to the fourth embodiment. In the semiconductor module (FIG. 7) according to the third embodiment, a cavity is formed between a device layer 30 and a mounting substrate 80. In contrast, in the semiconductor module according to the fourth embodiment, as in the semiconductor module (FIG. 4) according to the second embodiment, a first member 85 is disposed between the device layer 30 and the mounting substrate 80. The dielectric dissipation factor of the first member 85 is smaller than the dielectric dissipation factor of a mold material 86.

Next, excellent effects of the fourth embodiment are described.

Even in the fourth embodiment, as in the third embodiment, it is possible to reduce electrical loss caused by the dielectric dissipation factor. Further, as in the second embodiment, it is possible to increase resistance against external force or stress. Preferable magnitude relationships between the dielectric dissipation factor of the resin layer 50 and the dielectric dissipation factor of the first member 85 are the same as those in the second embodiment.

The embodiments above are only exemplifications and it is obvious that structures described in different embodiments can be partly replaced or combined. Operational effects that are the same as operational effects resulting from structures that are the same as the structures of a plurality of embodiments are not mentioned one by one for each embodiment. Further, the present disclosure is not limited to the embodiments above. For example, it is obvious to those skilled in the art that various changes, improvements, or combinations are possible.

What is claimed is:

1. A semiconductor module comprising:
a mounting substrate that has a mounting surface;
a semiconductor device that includes a device layer where an electronic circuit including a semiconductor element is configured, an insulating layer that is on one of surfaces of the device layer, and a plurality of bumps that are on another of the surfaces of the device layer, the semiconductor device being mounted on the mounting substrate with the another of the surfaces, where the plurality of bumps are disposed, of the device layer facing the mounting surface;
a resin layer that is on a surface of the insulating layer on a side opposite to the device layer; and
a mold material that is on a region of the mounting surface on an outer side portion of the semiconductor device in plan view, a side surface of the semiconductor device, and at least a side surface of the resin layer,
wherein a dielectric dissipation factor of the resin layer is smaller than a dielectric dissipation factor of the mold material.

2. The semiconductor module according to claim 1, wherein
the mold material covers a surface of the resin layer on a side opposite to a surface of the resin layer facing the mounting substrate.

3. The semiconductor module according to claim 1, further comprising:
a first member that includes resin and that is in a space between the device layer and the mounting surface of the mounting substrate,
wherein a dielectric dissipation factor of the first member is smaller than the dielectric dissipation factor of the mold material.

4. The semiconductor module according to claim 3, wherein
the device layer includes an element formation layer where the semiconductor element is configured, and a multilayer wire layer that is on the element formation layer, the element formation layer being between the multilayer wire layer and the insulating layer,
wherein
the semiconductor device further includes an insulating protective film that is on a surface of the multilayer wire layer facing a side opposite to the element formation layer, and
a thickness of the protective film is smaller than a thickness of the insulating layer, and the dielectric dissipation factor of the first member is smaller than the dielectric dissipation factor of the resin layer.

5. The semiconductor module according to claim 4, wherein
at least one of the plurality of bumps is configured as a terminal for inputting a high-frequency signal, at least one of other ones of the plurality of bumps is configured as a terminal for outputting the high-frequency signal, and a length of a shortest line segment of line segments, each connecting, in plan view, a geometric center of the terminal for inputting the high-frequency signal and a geometric center of the terminal for outputting the high-frequency signal, is greater than or equal to 100 μm.

6. The semiconductor module according to claim 3, wherein
the device layer includes an element formation layer where the semiconductor element is configured, and a multilayer wire layer that is on the element formation layer, the element formation layer being between the multilayer wire layer and the insulating layer,
the semiconductor device further includes an insulating protective film that is on a surface of the multilayer wire layer facing a side opposite to the element formation layer, and
a thickness of the protective film is greater than or equal to a thickness of the insulating layer, and the dielectric dissipation factor of the resin layer is smaller than the dielectric dissipation factor of the first member.

7. The semiconductor module according to claim 6, wherein
at least one of the plurality of bumps is configured as a terminal for inputting a high-frequency signal, at least one of other ones of the plurality of bumps is configured as a terminal for outputting the high-frequency signal, and a length of a shortest line segment of line segments, each connecting, in plan view, a geometric center of the terminal for inputting the high-frequency signal and a geometric center of the terminal for outputting the high-frequency signal, is less than 100 μm.

8. The semiconductor module according to claim 1, wherein
the mold material closely contacts the region of the mounting surface on the outer side portion of the semiconductor device in the plan view, the side surface of the semiconductor device, and at least the side surface of the resin layer.

9. The semiconductor module according to claim 1, wherein
an air gap is between the mold material and a region of at least a portion of the side surface of the semiconductor device and a region of at least a portion of the side surface of the resin layer.

10. The semiconductor module according to claim 2, further comprising:
a first member that includes resin and that is in a space between the device layer and the mounting surface of the mounting substrate,
wherein a dielectric dissipation factor of the first member is smaller than the dielectric dissipation factor of the mold material.

11. The semiconductor module according to claim 2, wherein
the mold material closely contacts the region of the mounting surface on the outer side portion of the semiconductor device in the plan view, the side surface of the semiconductor device, and at least the side surface of the resin layer.

12. The semiconductor module according to claim 3, wherein
the mold material closely contacts the region of the mounting surface on the outer side portion of the semiconductor device in the plan view, the side surface of the semiconductor device, and at least the side surface of the resin layer.

13. The semiconductor module according to claim 4, wherein
the mold material closely contacts the region of the mounting surface on the outer side portion of the semiconductor device in the plan view, the side surface of the semiconductor device, and at least the side surface of the resin layer.

14. The semiconductor module according to claim 5, wherein
the mold material closely contacts the region of the mounting surface on the outer side portion of the semiconductor device in the plan view, the side surface of the semiconductor device, and at least the side surface of the resin layer.

15. The semiconductor module according to claim 2, wherein
an air gap is between the mold material and a region of at least a portion of the side surface of the semiconductor device and a region of at least a portion of the side surface of the resin layer.

16. The semiconductor module according to claim 3, wherein
an air gap is between the mold material and a region of at least a portion of the side surface of the semiconductor device and a region of at least a portion of the side surface of the resin layer.

17. The semiconductor module according to claim 4, wherein
an air gap is between the mold material and a region of at least a portion of the side surface of the semiconductor device and a region of at least a portion of the side surface of the resin layer.

18. The semiconductor module according to claim 5, wherein
an air gap is between the mold material and a region of at least a portion of the side surface of the semiconductor device and a region of at least a portion of the side surface of the resin layer.

19. A method of producing a semiconductor module, comprising:
preparing an SOI wafer in which an insulating layer and a device layer that includes a semiconductor are placed on a base substrate that includes a semiconductor, and in which a plurality of chip regions are defined;
forming a plurality of semiconductor elements on each of the plurality of chip regions of the device layer;
forming a multilayer wire layer on the device layer where the plurality of semiconductor elements are formed;
forming a plurality of bumps on the multilayer wire layer;
after forming the plurality of bumps, removing the base substrate and forming the SOI wafer into a thin layer;
disposing a resin layer on an exposed surface of the insulating layer of the SOI wafer that has been formed into the thin layer;
after disposing the resin layer, cutting the SOI wafer and the resin layer into individual parts to form a plurality of semiconductor devices;
mounting one of the plurality of semiconductor devices on a mounting surface of a mounting substrate by flip-chip mounting; and
covering with a mold material a region of the mounting surface on an outer side portion of the semiconductor device in plan view and at least a side surface of the semiconductor device,
wherein a dielectric dissipation factor of the resin layer is smaller than a dielectric dissipation factor of the mold material.

20. The method of producing a semiconductor module according to claim 19, further comprising:
after mounting the semiconductor device on the mounting substrate and before covering with the mold material, disposing a first member between the device layer and the mounting substrate, the first member including resin and having a dielectric dissipation factor that is smaller than the dielectric dissipation factor of the mold material.
